(19) United States
(12) Patent Application Publication
(10) Pub. No.: US 2016/0190513 A1
(43) Pub. Date: Jun. 30, 2016

(54) BARRIER FABRIC SUBSTRATE WITH HIGH FLEXIBILITY AND MANUFACTURING METHOD THEREOF

(71) Applicant: KOLON GLOTECH, INC., Gwacheon (KR)

(72) Inventors: Soo-Heon Kim, Yongin (KR); Byoung-Cheul Park, Seosan (KR); Beob Park, Yongin (KR)

(21) Appl. No.: 14/983,374

(22) Filed: Dec. 29, 2015

(30) Foreign Application Priority Data
Dec. 30, 2014 (KR) 10-2014-0193558

(51) Int. Cl. H01L 51/52; C23C 16/50; C23C 16/455

(52) U.S. Cl. CPC H01L 51/5256; C23C 16/45525; C23C 16/50; H01L 2251/5338

(57) ABSTRACT

A flexible barrier fabric substrate includes a fabric base material, a planarization layer formed on the fabric base material, and a barrier layer formed on the planarization layer. One or more inorganic thin film layers and one or more polymer thin film layers are alternately stacked in the barrier layer.

### CROSS-REFERENCE TO RELATED APPLICATIONS

This application claims priority to Korean Patent Application No. 10-2014-0193558, filed in the Korean Intellectual Property Office on Dec. 30, 2014, which is incorporated herein by reference in its entirety.

### BACKGROUND

The present disclosure relates to a barrier fabric substrate with high flexibility and a manufacturing method thereof. Specifically, the present disclosure relates to a barrier fabric substrate with high flexibility, which employs fiber as a base material, a manufacturing method thereof, and a wearable display or flexible lighting device including the barrier fabric substrate.

Flexible devices, which include integrated devices such as a display, a circuit, a battery and a sensor on a substrate formed of a flexible plastic material by using organic and/or inorganic materials to use deposition and printing processes, are advantageously light, thin, and impact resistant. Accordingly, it is expected that the flexible devices will replace current flat panel displays and lighting, and the like, and studies have been actively conducted to create flexible devices.

However, organic electronic devices mounted on a flexible substrate are vulnerable to the permeation of moisture or oxygen. Plastic material substrates also have high moisture and oxygen permeability. For that reason, there is difficulty in implementing a flexible device, and for example, it is difficult to construct flexible displays including organic light-emitting diodes (OLEDs).

Accordingly, studies have been conducted to design effective barriers and encapsulation layers that block moisture and oxygen, in order to manufacture an organic electronic device having a long service life. Although the upper and lower portions of early organic electronic devices were initially encapsulated busing a glass or metal lid as a barrier and an encapsulation layer, moisture could still permeate through sealants used between the substrates and the barrier and/or the encapsulation layers. Furthermore, since the barrier and/or the encapsulation layers were inflexible, they were difficult to apply to flexible devices. As an alternative for overcoming the disadvantage of the glass or metal lid, barrier or encapsulation layers may include inorganic thin films, organic thin films, or organic/inorganic multi-layer thin films which are a combination thereof.

However, even though barrier and encapsulation technology has been developed, current plastic material substrates have limitations. For example, plastic material substrates may only be bent in one direction, have no drape characteristics due to low bending recoverability, and thus may fail to properly utilize the advantage of flexibility. In order to manufacture wearable devices or bendable devices which are not mountable, electronic device elements need to be formed in a parent material or a base material which is wearable, such as fabric. For this purpose, there is a need for a new barrier technology, which may reduce the porosity of fabric, but without reducing its flexibility.

### SUMMARY OF THE DISCLOSURE

The present disclosure has been made in an effort to provide a fabric substrate having barrier properties at a level similar to glass, and which may be applied to a wearable display or flexible lighting. The present disclosure has been made in an effort to implement a wearable IT device, rather than a mountable or attachable IT device. However, the present disclosure may be applied to a mountable or attachable IT device.

An embodiment of the present disclosure provides a flexible barrier fabric substrate including: a fabric base material; a planarization layer formed on the fabric base material; and a barrier layer formed on the planarization layer, in which one or more inorganic thin film layers and one or more polymer thin film layers are alternately stacked in the barrier layer.

According to an embodiment of the present disclosure, it is preferred that among a plurality of layers included in the barrier layer, both an innermost layer brought into contact with the planarization layer and an outermost layer maximally spaced apart from the planarization layer are an inorganic thin film layer.

According to another embodiment of the present disclosure, it is preferred that among a plurality of layers included in the barrier layer, both the innermost layer brought into contact with the planarization layer and the outermost layer maximally spaced apart from the planarization layer are a polymer thin film layer.

According to still another embodiment of the present disclosure, it is preferred that in the barrier layer, an inorganic thin film layer, a polymer thin film layer, and an inorganic thin film layer are sequentially stacked on the planarization layer.

According to yet another embodiment of the present disclosure, the fabric base material may be a woven fabric formed of a material composed of polyethylene terephthalate, polyethylene naphthalate, polyethylene, nylon, acryl or a mixture thereof.

According to still yet another embodiment of the present disclosure, it is preferred that the planarization layer includes one or more selected from the group consisting of silane, polycarbonate, acrylate-based polymers, amine-based oligomers, and vinyl-based polymers.

According to another embodiment of the present disclosure, it is preferred that the inorganic thin film layer is composed of oxides, nitrides, carbides, oxynitrides, nitride carbides or oxynitride carbides including one or more metal elements selected from the group consisting of silicon, aluminum, titanium, zinc, and zirconium.

According to a still another embodiment of the present disclosure, it is preferred that the polymer thin film layer is composed of tris(trimethylsiloxy)(vinyl)silane represented by the following Formula 1.

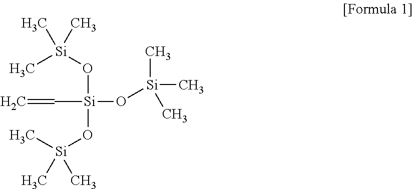 [SMILES: C=C[Si](O[Si](C)(C)C)(O[Si](C)(C)C)O[Si](C)(C)C]

According to a yet another embodiment of the present disclosure, it is preferred that the inorganic thin film layer has a thickness of about 10 to 50 nm.

According to a still yet another embodiment of the present disclosure, it is preferred that the polymer thin film layer has a thickness of about 20 to 100 nm.

Another embodiment of the present disclosure provides a method for manufacturing a flexible barrier fabric substrate, the method including: forming a planarization layer on a fabric base material; forming a first barrier layer as an inorganic thin film layer or a polymer thin film layer on the planarization layer; forming a second barrier layer as an inorganic thin film layer or a polymer thin film layer such that a material for the second barrier layer and a material for the first barrier layer are alternately stacked on the first barrier layer; and stacking a third barrier layer on the second barrier layer by again using the same configuration as the first barrier layer.

According to an embodiment of the present disclosure, the method may further include repeating the forming of the second barrier layer and the forming of the third barrier layer one or more times.

According to another embodiment of the present disclosure, it is preferred that the inorganic thin film layer is formed by an atomic layer deposition method.

According to still another embodiment of the present disclosure, it is preferred that the polymer thin film layer is formed by a plasma enhanced chemical vapor deposition method.

Still another embodiment of the present disclosure may provide a flexible display device or a flexible lighting device, which includes a substrate having a configuration according to the present disclosure.

The fabric substrate according to the present disclosure provides a multi-layer barrier layer including one and more polymer thin film layers and one and more inorganic thin film layers, which are prepared by using organic/inorganic precursor materials, and thus, may effectively suppress oxygen or moisture from permeating into an organic electronic device, thereby preventing the device from deteriorating.

The polymer thin film layer applied to the present disclosure is excellent in flexibility, and thus, may implement flexibility of a fabric substrate as it is when applied to an organic electronic device.

Since the fabric substrate according to the present disclosure keeps high flexibility, it is expected that a change from a mountable or attachable IT device to a wearable IT device may be achieved when the fabric substrate according to the present disclosure is used. Accordingly, it is possible to use the fabric substrate according to the present disclosure as a substrate of a wearable display device and a flexible lighting device.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view schematically illustrating a configuration of a fabric substrate according to an embodiment of the present disclosure.

FIG. 2 is a view illustrating a cross-sectional configuration of a fabric substrate in which a fabric base material 100, a planarization layer 200, an inorganic thin film layer 301, a polymer thin film layer 302, and an inorganic thin film layer 301 are sequentially stacked, according to an embodiment of the present disclosure.

FIG. 3 is a view simply illustrating a process flow of manufacturing a fabric substrate according to an embodiment of the present disclosure.

FIG. 4 is a scanning electron microscope (SEM) image illustrating (a) a side-cross section and (b) a surface state of a fabric base material after a planarization layer is formed on the fabric base material of an organic electronic device according to embodiments of the present disclosure.

FIG. 5 is a graph illustrating the result of measuring the firmness of a fabric substrate according to embodiments of the present disclosure.

FIG. 6 is a graph illustrating the result of measuring the water vapor transmission rate of a fabric substrate according to embodiments of the present disclosure.

FIG. 7 is a view illustrating an apparatus for measuring the oxidation degree of calcium as a change in electrical properties in order to measure the water vapor transmission rate of the fabric substrate according to embodiments of the present disclosure.

FIG. 8 is a graph illustrating the result of measuring the water vapor transmission rate of the fabric substrate according to embodiments of the present disclosure as the oxidation degree of calcium.

It should be understood that the appended drawings are not necessarily to scale, and may prevent a somewhat simplified representation of various features illustrative of the basic principles of the disclosure. The specific design features of the present disclosure as disclosed herein, including, for example, specific dimensions, orientations, locations, and shapes will be determined in part by the particular intended application and use environment.

In the figures, reference numbers refer to the same or equivalent parts of the present disclosure throughout the several figures of the drawing.

### DETAILED DESCRIPTION

Hereinafter, the present disclosure will be described in detail with reference to the drawings. In describing the present disclosure, detailed descriptions related to publicly known functions or configurations will be omitted in order not to obscure the gist of the present disclosure.

The term “flexible” is broad in meaning. For example, a parent material such as a plastic film is flexible even though it may not be worn, that is, it may not be suitable for use in an ultimate wearable base material or a lighting device with high flexibility. A substrate using fabric may have excellent firmness and crease recovery, which are inherent drape properties of fabric, but fabric may not impart barrier properties due to poor surface roughness and numerous pores. Thus, the present inventors have developed a fabric substrate which may be used as a parent material for a wearable device, which may be worn like clothes while having barrier properties at a level similar to glass.

The present disclosure relates to a fabric substrate which may be applied to a wearable display or a flexible device such as flexible lighting. The fabric substrate according to an embodiment of the present disclosure includes: a fabric base material; a planarization layer formed on the fabric base material; and a barrier layer formed on the planarization layer, in which one or more inorganic thin film layers and one or more polymer thin film layers are alternately stacked in the barrier layer.

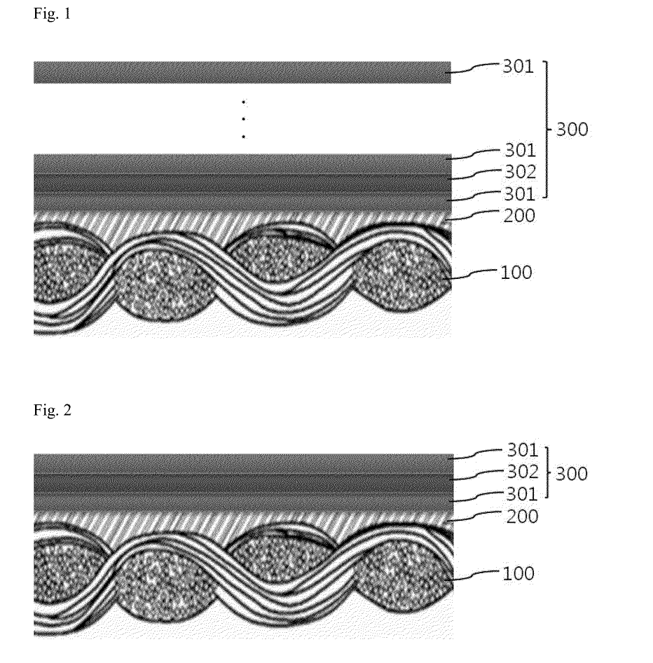

First, referring to FIG. 1, the configuration of the fabric substrate according to an embodiment of the present disclosure will be described. FIG. 1 is a view schematically illustrating a configuration of a fabric substrate according to an embodiment of the present disclosure.

As illustrated in FIG. 1, the fabric substrate according to an embodiment of the present disclosure includes: a fabric base material 100; a planarization layer 200 for planarizing the fabric base material; and a barrier layer 300 formed on the planarization layer 200, which blocks gas and moisture. The barrier layer 300 is a film in which an inorganic thin film layer 301 and a polymer thin film layer 302 are alternately stacked, and may have a structure in which one or more inorganic thin film layers and one or more polymer thin film layers are alternately stacked. A fabric substrate in which numerous pores of the fabric base material are filled and flexibility is still secured is provided by the configuration.

Hereinafter, each configuration element of the fabric substrate will be described in detail.

The fabric base material 100 may be a woven fabric formed of a material composed of polyethylene terephthalate, polyethylene naphthalate, polyethylene, nylon, acryl or a mixture thereof. The fabric base material 100 may include a material with high thermal stability, such as polyethylene terephthalate, polyethylene naphthalate, or a mixture thereof.

The thickness of the woven fabric constituting the fabric base material 100 is not particularly limited, but is suitably about 50 to 230 μm. In an embodiment, the woven fabric can have a thickness of about 50 to 150 μm, and more specifically about 50 to 100 μm. The thickness of the woven fabric may be chosen in consideration of the desired thickness of the final substrate.

Because the surface roughness of the woven fabric may be in a range of about 25 to 50 μm, which is a high value, a barrier layer formed on the woven fabric may have poor barrier performance. Accordingly, it may be necessary to planarize the fabric base material 100 including the woven fabric.

The planarization layer 200 may include a material that can secure thermal stability and flexibility, such as one or more materials selected from a group consisting of silane, polycarbonate, an acrylate-based polymer, an amine-based oligomer, and a vinyl-based polymer.

The planarization film may have a thickness of about 0.01 to 5 μm and a surface smoothness (Ra) of about 5 to 300 nm, and thus, may improve the adherence of a gas blocking film to the substrate.

If the planarization layer 200 includes a silane, the silane may be one or more selected from the group consisting of monosilane (SiH₄), disilane (Si₂H₆), trisilane (Si₃H₈), and tetrasilane (Si₄H₁₀). Further, the silane may include one or more functional groups selected from the group consisting of an epoxy group, an alkoxy group, a vinyl group, a phenyl group, a methacryloxy group, an amino group, a chlorosilanyl group, a chloropropyl group, and a mercapto group.

The planarization layer 200 may further include a light-absorbing material, such as one or more materials selected from the group consisting of benzophenone-based, oxalanilide-based, benzotriazole-based, and triazine-based light-absorbing materials.

The barrier layer 300 may block gas and moisture. The barrier layer 300 may include a film including an inorganic thin film layer 301 and a polymer thin film layer 302 stacked together. In an embodiment, the barrier layer 300 may include a plurality of organic thin film layers 301 and polymer thin film layers 302 that are alternately stacked.

Inorganic materials have low diffusion rates and low solubility, and thus, have excellent properties as barrier layers to prevent the permeation of moisture. However, when the barrier layer 300 includes only inflexible inorganic materials, a flexible device mounted on a substrate with the barrier layer 300 may become physically damaged. Furthermore, it is possible that moisture permeability may be increased and the barrier performance deteriorates.

Accordingly, in the present disclosure, the barrier layer 300 may include a polymer thin film stacked with an inorganic thin film, thereby providing a multi-layer barrier thin film. The polymer thin film may be obtained by using an organic/inorganic hybrid precursor compound represented by the following Formula 1 and having a Si—O bond. The polymer thin film may planarize the surface of the thin film and lengthen the diffusion path of the barrier thin film, in order to lower the water vapor transmission rate and improve barrier performance. Furthermore, the barrier layer 300 may have high barrier performance and a relatively thin thickness compared to barriers applied to organic electronic devices of the prior art, and may have high flexibility.

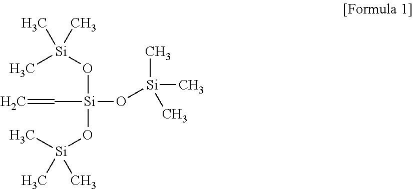 [SMILES: C=C[Si](O[Si](C)(C)C)(O[Si](C)(C)C)O[Si](C)(C)C]

A method of forming a barrier layer having alternately stacked inorganic thin film layers and the polymer thin film layers is not particularly limited. According to an embodiment of the present disclosure, the barrier layer 300 may include a plurality of layers, which may include both an innermost layer brought into contact with the planarization layer 200 and an outermost layer maximally spaced apart from the planarization layer 200. The innermost layer and the outermost layer may both be inorganic thin film layers or polymer thin film layers. As illustrated in FIG. 2, an embodiment may have a configuration in which an inorganic thin film layer 301, a polymer thin film layer 302, and an inorganic thin film layer 301 are sequentially stacked on the planarization layer 200.

The inorganic thin film layer 301 may be composed of oxides, nitrides, carbides, oxynitrides, nitride carbides, or oxynitride carbides including one or more metal elements selected from the group consisting of silicon, aluminum, titanium, zinc, and zirconium. In an embodiment, the inorganic film layer 301 may include one or more oxides.

The inorganic thin film layer 301 may have a thickness of preferably about 10 nm to 50 nm. When the thickness is less than 10 nm, barrier properties are slight, and when the thickness is more than 50 nm, flexibility deteriorates, and thus, defects such as cracks and pinholes may be easily generated in the inorganic thin film layer 301, which is not preferred.

The polymer thin film layer 302 may be a layer obtained by depositing tris(trimethylsiloxy)(vinyl)silane (TTMSVS) represented by the following Formula 1 using a plasma enhanced chemical vapor deposition method. The TTMSVS thin film deposited by plasma may adhere well to the inorganic layer 301. The TTMSVS may cover pinhole defects, planarize the surface of the polymer thin film layer 302, and lengthen the diffusion path of the barrier layer 300 even when TTMSVS layer 302 has a small thickness, thereby imparting high barrier performance. Further, TTMSVS may be used as an intermediate interlayer, in order to minimize cracks when the fabric base material is bent, thereby maintaining the advantageous flexibility of the fabric base material. When TTMSVS is stacked on the inorganic thin film layer 301, TTMSVS may be very suitable as a barrier material for the fabric base material.

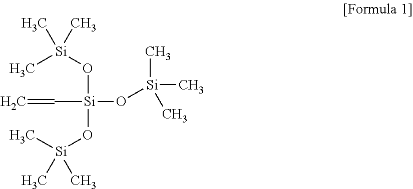 [SMILES: C=C[Si](O[Si](C)(C)C)(O[Si](C)(C)C)O[Si](C)(C)C]

The polymer thin film layer 302 may have a thickness of about 20 to 100 nm, which is preferred because it is possible to prevent cracks from generating when the polymer thin film layer 302 is bent. When the thickness is less than 20 nm, the diffusion may not be sufficient, and thus, improvement in barrier properties may be minimal, and when the thickness is more than 100 nm, flexibility and barrier properties during bending may deteriorate, which is not preferred.

The fabric substrate obtained by stacking the inorganic thin film layer 301 and the polymer thin film layer 302 according to the present disclosure uses fabric as a parent material, and may have gas barrier properties even in a barrier layer configuration with a small thickness. Thus, the fabric substrate may be easily applied to a wearable display or a substrate of flexible lighting.

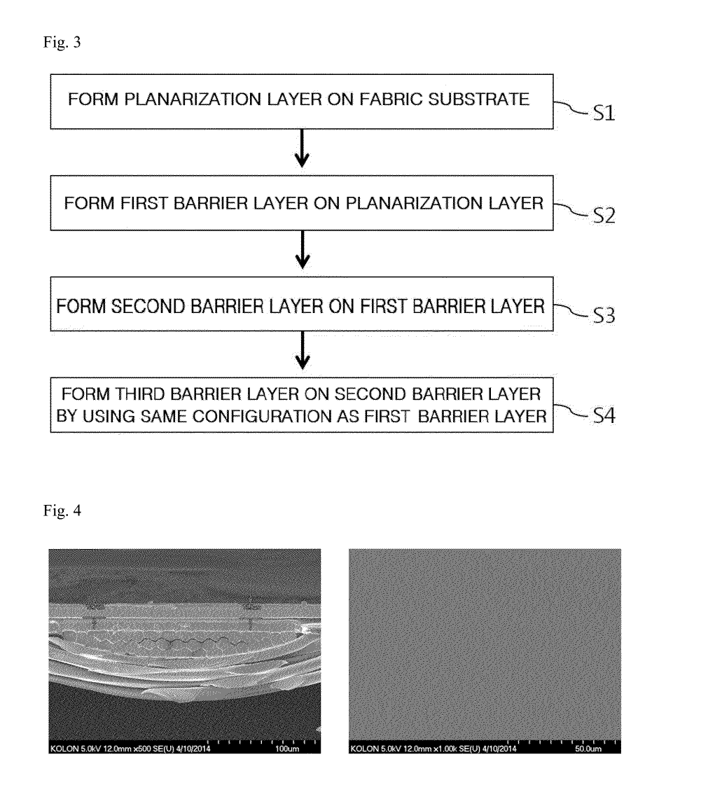

Next, the method for manufacturing a fabric substrate according to the present disclosure will be described with reference to FIG. 3. FIG. 3 is a view simply illustrating a process flow of manufacturing a fabric substrate according to an embodiment of the present disclosure.

According to FIG. 3, the fabric substrate is manufactured by the method including: forming a planarization layer on a fabric base material at S1; forming a first barrier layer as an inorganic thin film layer or a polymer thin film layer on the planarization layer at S2; forming a second barrier layer on the first barrier layer at S3, the second barrier layer being an inorganic thin film layer or a polymer thin film layer such that a material for the second barrier layer and a material for the first barrier layer are different; and stacking a third barrier layer on the second barrier layer by again using the same film type as that of the first barrier layer at S4. Steps S3 and S4 may be repeated one or more times until the fabric substrate becomes a material for the outermost layer to be obtained.

The constituent components of embodiments of the fabric base material, the planarization layer, the inorganic thin film layer, and the polymer thin film layer are described above, and thus, the detailed description thereof will be omitted.

Step S1 of forming of the planarization layer on the fabric base material in the fabric substrate is performed in order to impart smoothness to the fabric base material. The fabric base material may be formed of a woven fabric material composed of polyethylene terephthalate, polyethylene naphthalate, or a mixture thereof. Since the fabric is woven as a 3D structure, the fabric has numerous pores and high surface roughness, and thus, may not suitable for use as a substrate for forming an electronic device alone. For example, an organic electronic device may not be mounted directly on the fabric base material, due to the high surface roughness and porosity of the fabric base material. Accordingly, a planarization layer may be formed on a fabric base material in order to fill the pores of the fabric base material and lower the surface roughness.

The planarization layer may be formed on the fabric base material using a transfer method including lamination, a slot coating method, or a spin coating method. In contrast to other coating methods, the lamination method may include: applying a coating material which constitutes a planarization layer on a release film, and detaching the release film while laminating the coating material on the fabric base material. The lamination method may reduce the surface roughness of the fabric base material to about 1 to 10 nm. When the release film has a very high degree of planarization, the planarization layer may also have a very high degree of planarization.

The planarization layer may include a material that lowers the surface roughness of the fabric base material, while not affecting firmness or crease recovery. The planarization layer may include one or more selected from the group consisting of silane, polycarbonate, acrylate-based polymers, amine-based oligomers, and vinyl-based polymers. The planarization layer may reduce the surface roughness of the fabric base material to 10 nm or less. For this purpose, the planarization layer may be be formed so as to have a thickness of about 0.01 to 5 μm and a surface smoothness (Ra) of about 5 to 300 nm.

Step S2 includes forming the first barrier layer as an inorganic thin film layer or a polymer thin film layer on the planarization layer. In an embodiment, the first barrier layer may be a first inorganic thin film layer formed on the planarization layer, in order to impart high barrier performance for gas diffusion and moisture permeation.

Steps S3 and S4 include forming a second barrier layer and a third barrier layer in an alternating stack structure. That is, the second barrier layer as the polymer thin film layer may be formed on the first inorganic thin film layer, and the third barrier layer may be formed on the polymer thin film layer. Steps S3 and S4 may be repeated one or more times until the outermost layer is obtained. Specifically, as illustrated in FIG. 2, after the polymer thin film layer is formed at step S3, and then the second inorganic thin film layer is formed in step S4, complete fabric substrate including the outermost layer may be obtained by performing steps S3 and S4 each one time. However, in an embodiment, steps S3 and S4 may be repeated multiple times, thereby forming a plurality of alternately stacked inorganic thin film layers and polymer thin film layers.

In an embodiment, each inorganic thin film layer may be formed using an atomic layer deposition method. The atomic layer deposition method may reduce generation of pinholes in each inorganic thin film layer, and the reduction is based on the self-limiting reaction. The atomic layer deposition method suppresses pinholes from being formed in the thin film at a low process temperature of 100° C. or less, and also facilitates the manufacture of a thin film, which may be preferred. In an embodiment, each inorganic thin film layer may be deposited in a thickness of about 10 to 50 nm or less.

In an embodiment, each polymer thin film layer may be deposited by a plasma enhanced chemical vapor deposition method. Using this method, each polymer thin film may have a dense structure, be fabricated without curing, and have improved polymer properties. Each polymer thin film layer may be deposited in a thickness of about 20 to 100 nm or less.

The fabric substrate according to the present disclosure has high flexibility and may be substantially impermeable to gas and moisture by including a barrier structure having stacked inorganic thin film and the polymer thin film layers. Accordingly, the fabric substrate may be applied to a wearable display, and may also be applied to a flexible organic electronic device, specifically, various products such as an organic light emitting diode, an organic solar cell, or an organic thin film transistor.

### 1. Example

In an example of the present disclosure, the planarization layer 200 is stacked on a fabric base material 100 composed of a mixture of polyethylene terephthalate and polyethylene naphthalate. The fabric base material may have a thickness of 75 μm. The planarization layer 200 may be stacked on the fabric base material 100 by using a transfer method, which includes lamination of a silane-based resin including an epoxy group.

The first inorganic thin film layer 301 may be formed of Al₂O₃ and have a thickness of 10 to 50 nm using the atomic layer deposition method. And then, the polymer thin film layer 302 may be formed of TTMSVS and have a thickness of 50 to 80 nm using a plasma enhanced chemical vapor deposition method. And then, a fabric substrate was manufactured by again forming a second inorganic thin film layer 301 of Al₂O₃ using the atomic layer deposition method. The second inorganic thin film layer 301 may have a thickness of 10 to 50 nm.

FIG. 4 shows the surface roughness of the side-cross section and the surface of the fabric base material, according to an embodiment of the present disclosure. FIG. 4 confirms whether the smoothness of the fabric substrate was improved by the planarization layer. According to FIG. 4(a), the planarization layer according to an embodiment of the disclosure is very uniformly formed and the surface state (FIG. 4(b)) is considerably smooth. Thus, the high surface roughness of the woven fabric may be reduced by using the planarization layer. The surface roughness of the fabric base material in which the planarization layer applied at a thickness of 5 nm or less allows the barrier layer to be uniformly formed on the planarization layer.

A. Measurement of Firmness

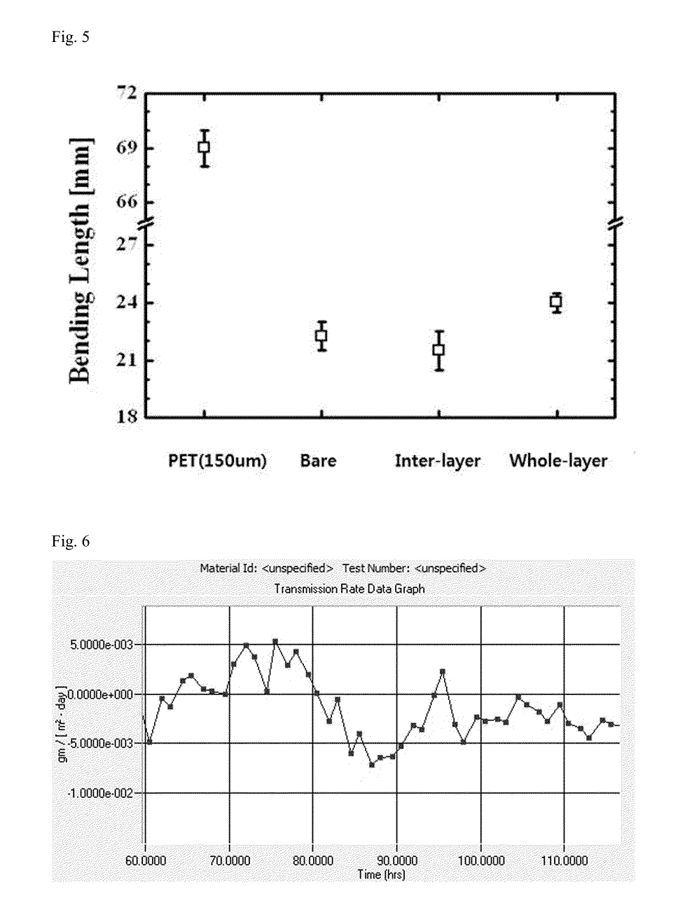

In order to evaluate the flexibility of the fabric substrate, firmness, which relates to the degree of flexibility of fabric, was measured for each step of manufacturing the fabric substrate, and the results are shown in FIG. 5 and Table 1.

The firmness is a measure related to the degree of stiffness and softness of a fabric line, and to resistance to movement of cloth. The firmness affects texture and drape properties of cloth. The firmness is measured by a cantilever method (ISO 4064:2011). The cantilever method includes placing a test specimen on an inclined plane at an angle of 41.5 degrees, and measuring the length in which the front end of the test specimen touches. A smaller value indicates better firmness properties.

TABLE 1

| | | Fabric base | After coating the | Final |
|---|---|---|---|---|
| | PET Film | material | planarization | fabric |
| Classification | (150 μm) | (100) | layer (200) | substrate |
| Firmness (mm) | 69 | 23 | 22 | 25 |

According to FIG. 5 and Table 1, it can be seen that the firmness of the fabric substrate is much better than that of the PET film, and is minimally different from that of the fabric base material. Accordingly, the fabric substrate according to the present disclosure may maintain the flexibility of the fabric base material, and thus, may be utilized as a substrate for a device, which requires high flexibility like a wearable display.

B. Measurement of Water Vapor Transmission Rate

The water vapor transmission rate of the fabric substrate according to an embodiment of the disclosure was evaluated. The water vapor transmission rate (WVTR) was measured by a commercially available measurement apparatus (capable of measuring up to WVTR <5×10⁻³ g/m²/day) from MOCON Inc., which is typically used during the measurement, and the results are illustrated in FIG. 6. The apparatus is used to perform the measurement by fixing a sample substrate to be analyzed to a holder, continuously spraying a fixed amount of moisture onto one surface to pass through the sample substrate, and then capturing the amount of moisture at the opposite side using a sensor, and quantifying the amount. According to FIG. 6, it can be seen that the fabric substrate manufactured in the Example has a water vapor transmission rate of 5×10⁻³ g/m²/day or less, and is excellent in blocking performance even after it has been exposed to moisture for a long time period.

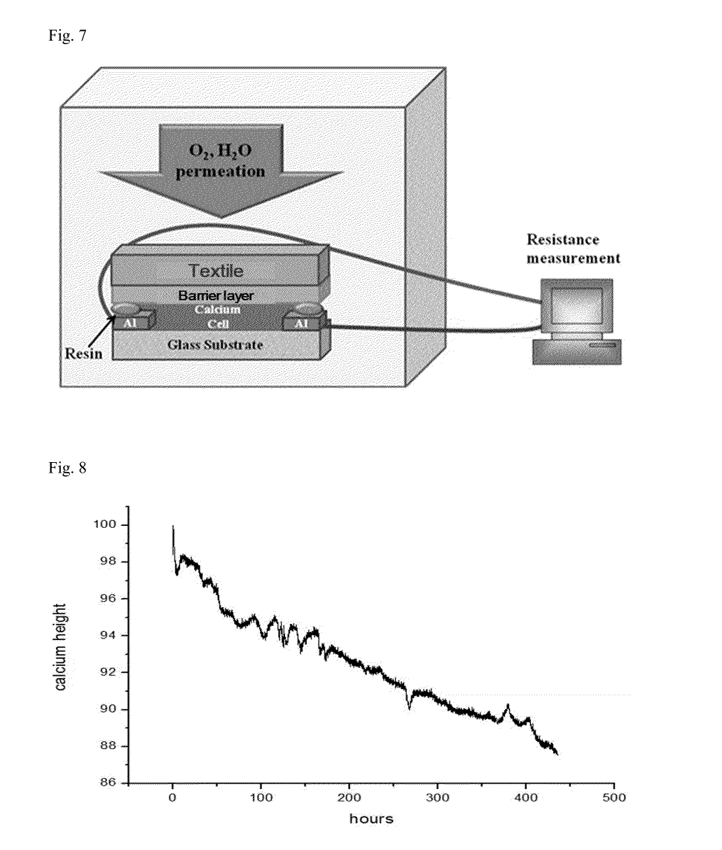

A so-called Ca-test was performed in combination for evaluation in order to quantitatively measure the water vapor transmission rate of the fabric substrate tested in a more accurate manner. The oxidation degree of calcium illustrated in FIG. 7 was evaluated by using an apparatus for measuring the degree of oxidation by measuring a change in electrical properties. The apparatus takes advantage of an oxidation phenomenon. Metallic calcium may have conductive properties, but becomes oxidized in the presence of moisture. Calcium oxide is an inorganic, electrically insulative material. Thus, the apparatus may be used to estimate an amount of moisture by measuring the conductivity of a calcium cell.

The Ca-test was used to measure the amount of moisture permeating a barrier layer according to an embodiment of the present disclosure by arranging the fabric substrate on the calcium cell. Specifically, the barrier layer of the fabric substrate was placed on the calcium cell. After arranging the fabric substrate on the apparatus, a current value across the calcium cell was quantitatively analyzed. The current value was measured by applying a positive voltage to both electrodes. The current value changed over time based on a change in resistance over time.

FIG. 8 illustrates a result of the Ca-test, and the resulting water vapor transmission rate was calculated according to the following equation. As a result, the water vapor transmission rate of the fabric substrate obtained in the Example was 9×10⁻⁴ g/m²/day, indicating that the moisture blocking performance of the fabric substrate was excellent.

WVTR=1.54×(36/40.1)×0.001×(delta H)×(24/delta T) <Equation 1>

delta H: an amount of calcium height changed

delta H: elapsed time (hours)

As described above, the embodiments have been described and illustrated in the drawings and the specification. The embodiments were chosen and described in order to explain certain principles of the disclosure and their practical application, to thereby enable others skilled in the art to make and utilize various embodiments of the present disclosure, as well as various alternatives and modifications thereof. As is evident from the foregoing description, certain aspects of the present disclosure are not limited by the particular details of the examples illustrated herein, and it is therefore contemplated that other modifications and applications, or equivalents thereof, will occur to those skilled in the art. Many changes, modifications, variations and other uses and applications of the present construction will, however, become apparent to those skilled in the art after considering the specification and the accompanying drawings. All such changes, modifications, variations and other uses and applications which do not depart from the spirit and scope of the disclosure are deemed to be covered by the disclosure which is limited only by the claims which follow.

What is claimed is:

1. A flexible barrier fabric substrate, comprising:
a fabric base material;
a planarization layer disposed on the fabric base material; and
a barrier layer disposed on the planarization layer,
wherein the barrier layer includes a plurality of inorganic thin film layers and a plurality of polymer thin film layers that are alternately stacked.

2. The flexible barrier fabric substrate of claim 1, wherein an innermost layer of the barrier layer in contact with the planarization layer and an outermost layer of the barrier layer that is maximally spaced apart from the planarization layer are inorganic thin film layers.

3. The flexible barrier fabric substrate of claim 1, wherein an innermost layer of the barrier layer in contact with the planarization layer and an outermost layer of the barrier layer that is maximally spaced apart from the planarization layer are polymer thin film layers.

4. The flexible barrier fabric substrate of claim 1, wherein in the barrier layer, an inorganic thin film layer, a polymer thin film layer, and an inorganic thin film layer are sequentially stacked on the planarization layer.

5. The flexible barrier fabric substrate of claim 1, wherein the fabric base material is a woven fabric including a material composed of polyethylene terephthalate, polyethylene naphthalate, polyethylene, nylon, acryl, or a mixture thereof.

6. The flexible barrier fabric substrate of claim 1, wherein the polarization layer comprises one or more selected from a group consisting of silane, polycarbonate, acrylate-based polymers, amine-based oligomers, and vinyl-based polymers.

7. The flexible barrier fabric substrate of claim 1, wherein the inorganic thin film layer comprises oxides, nitrides, carbides, oxynitrides, nitride carbides, or oxynitride carbides including one or more metal elements selected from the group consisting of silicon, aluminum, titanium, zinc, and zirconium.

8. The flexible barrier fabric substrate of claim 1, wherein the polymer thin film layer comprises tris(trimethylsiloxy)(vinyl)silane (TTMSVS) represented by Formula 1.

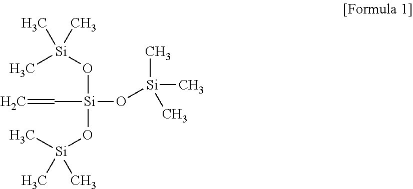 [SMILES: C=C[Si](O[Si](C)(C)C)(O[Si](C)(C)C)O[Si](C)(C)C]

9. The flexible barrier fabric substrate of claim 1, wherein the inorganic thin film layer has a thickness of 10 to 50 nm.

10. The flexible barrier fabric substrate of claim 1, wherein the polymer thin film layer has a thickness of 20 to 100 nm.

11. A method for manufacturing a flexible barrier fabric substrate, the method including:
forming a planarization layer on a fabric base material;
forming a first barrier film on the planarization layer, the first barrier film including an inorganic thin film layer or a polymer thin film layer;
forming a second barrier film on the first barrier film, the second barrier film including an inorganic thin film layer or a polymer thin film layer, the second barrier film including a different material than the first barrier film; and
forming a third barrier film on the second barrier film, the third barrier film including the same material as the first barrier film.

12. The method of claim 11, further comprising:
forming a plurality of alternately stacked barrier films on the third barrier film.

13. The method of claim 11, wherein the inorganic thin film layer is formed by an atomic layer deposition method.

14. The method of claim 11, wherein the polymer thin film layer is formed by a plasma enhanced chemical vapor deposition method.

15. A flexible display device comprising the substrate of claim 1.

16. A flexible lighting device comprising the substrate of claim 1.
